(19) United States
(12) Patent Application Publication
(10) Pub. No.: US 2010/0164022 A1
(43) Pub. Date: Jul. 1, 2010

(54) PMOS TRANSISTOR AND METHOD OF MANUFACTURING THE SAME

(76) Inventor: Jong-Won Sun, Gangnam-gu (KR)

Correspondence Address: SHERR & VAUGHN, PLLC, 620 HERNDON PARKWAY, SUITE 320, HERNDON, VA, 20170, US

(21) Appl. No.: 12/632,138

(22) Filed: Dec. 7, 2009

(30) Foreign Application Priority Data
Dec. 26, 2008 (KR) 10-2008-0134181

(51) Int. Cl. H01L 29/78; H01L 21/762

(52) U.S. Cl. 257/411; 438/458; 438/433; 257/E29.255; 257/E21.568; 257/E21.546

(57) ABSTRACT

A technique for manufacturing a PMOS transistor may be capable of lowering the electrostatic capacitance of a transistor so as to improve the operation characteristics of a PMOS device. A donor wafer may be bonded onto a wafer having a tunnel oxide film formed thereon, and patterning is performed so as to form PMOS transistors having very low resistance. It is difficult to control resistance only by control with salicide, so by using a method of manufacturing a PMOS transistor using an ion-implanted donor wafer, a PMOS transistor having very low resistance and being voltage-controllable can be formed.

The present application claims priority under 35 U.S.C. 119 to Korean Patent Application No. 10-2008-0134181 (filed on Dec. 26, 2008), which is hereby incorporated by reference in its entirety.

### BACKGROUND

In a method of manufacturing an NMOS/PMOS transistor of a related logic product, a gate oxide film may be formed on a semiconductor substrate, then polysilicon may be deposited. Subsequently N-type/P-type ions may be implanted so as to lower resistance. NMOS/PMOS transistors may be manufactured using this process.

With higher integration of semiconductor devices, the design rules are tending towards further miniaturization, and operation speeds are increasing. Accordingly, the size of a gate electrode of a transistor may be reduced. This may cause an increase in sheet resistance and contact resistance. To address this problem, a technique has been developed in which a metal silicide having low resistivity and a high melting point may be formed over a silicon substrate having gate electrodes and sources/drains. As a result, the resistance of the gate electrode and the contact resistance of the source/drain can be significantly lowered.

At first, a step of forming a silicide over the gate electrode and a step of forming a silicide over the source/drain are performed separately. However, in terms of process simplification and reduction in costs, salicide (Self Aligned Silicide) is developed in which the silicide may be formed over the gate electrode and the source/drain with a single step.

During the salicide formation process, a high melting point metal may be deposited simultaneously over a silicon layer and an insulating layer and a heat treatment may be performed on the metal. Then, the high melting point metal over the silicon layer undergoes a salicide reaction and is deformed into a salicide layer, but the high melting point metal over the insulating layer shows no salicide reaction. Accordingly, the unreacted high melting point metal may be selectively etched and removed such that only the salicide layer remains.

When a transistor is driven, very high resistance exists at the interface between the metal wire and the silicon (Si) substrate. For this reason, in order to form an ohmic contact between the metal and the silicon substrate, a compound of silicon and a metal (Co, Ti, Pt, W, or the like) may be used, and source/drain implantation with a high concentration is performed. Thus, resistance is controlled.

In a method of manufacturing an NMOS/PMOS transistor according to the related art operating as described above, when an NMOS/PMOS transistor of a logic product is manufactured, it is difficult to control the resistance and voltage (Vt) of the PMOS transistor, as compared with the NMOS transistor, and it is not easy to control resistance by ion implantation.

### SUMMARY

Embodiments relate to a technique for manufacturing a semiconductor device. In particular, embodiments relate to a P-channel metal oxide semiconductor (hereinafter, referred to PMOS) transistor having low resistance for a logic product, and to a method of manufacturing a PMOS transistor. Embodiments relate to a PMOS transistor which may be capable of easily controlling resistance and voltage, and a method of manufacturing a PMOS transistor.

Embodiments relate to a PMOS transistor which may be capable of lowering the electrostatic capacitance of a transistor so as to improve the operation characteristics of a PMOS device, and a method of manufacturing a PMOS transistor. Embodiments relate to a PMOS transistor which may be capable of forming a PMOS transistor having very low resistance by bonding an ion-implanted donor wafer onto a wafer having a tunnel oxide film formed thereon and patterning the donor wafer, and a method of manufacturing a PMOS transistor.

Embodiments relate to PMOS transistors which may include a logic wafer to which a donor wafer implanted with boron ions is bonded, and over which a shallow trench isolation is formed, and gate electrodes formed by performing a heat treatment on the bonded donor wafer, and after the heat treatment, by patterning the bonded donor wafer and performing reactive ion etching.

Embodiments relate to a method of manufacturing a PMOS transistor. The method may include the steps of: implanting the boron ions into a donor wafer; bonding the donor wafer implanted with boron ions onto a logic wafer having a shallow trench isolation formed therein; performing a heat treatment on the bonded donor wafer; and after the heat treatment, forming gate electrodes by patterning the bonded donor wafer and performing reactive ion etching.

According to embodiments, an ion-implanted donor wafer may be bonded onto a wafer having a tunnel oxide film formed thereon, and patterning is performed. In this case, instead of a known polysilicon gate, a p-type gate made of single-crystal silicon is formed. Therefore, a PMOS transistor having very low gate resistance can be formed.

### DRAWINGS

FIGS. 1A to 1C are process views showing a step of cutting a donor wafer according to embodiments.

FIGS. 2A to 2C are process views showing a process of manufacturing a PMOS transistor according to embodiments.

### DESCRIPTION

Embodiments relate to lowering the electrostatic capacitance of a transistor so as to improve the operation characteristics of a PMOS device. Specifically, an ion-implanted donor wafer may be bonded onto a wafer having a tunnel oxide film formed thereon, and patterning may be performed so as to form a PMOS transistor having very low resistance.

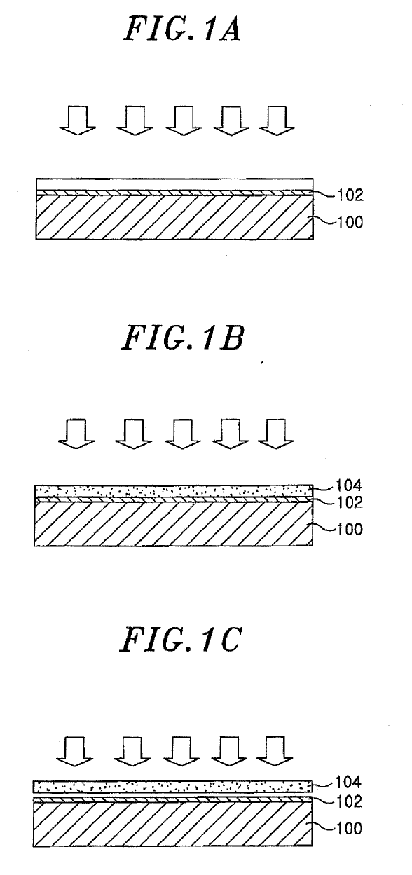

FIGS. 1A to 1C are process views showing a step of cutting a donor wafer according to embodiments. Referring to FIG. 1A, a silicon wafer may be prepared as a donor wafer 100, and hydrogen ions may be implanted into the prepared donor wafer 100. In this case, hydrogen ions, that is, H+ ions, may be implanted under the conditions that ion implantation energy is in a range of 13 to 16 kev. The dose of ions implanted may be in a range of 1×10¹⁵ to 5×10¹⁵ ions/cm³. Thus, a hydrogen ion implanted layer may be formed in the donor wafer 100.

Next, as shown in FIG. 1B, boron ions may be implanted into the hydrogen ion implanted layer 102 of the donor wafer 100. In this case, the boron ions to be used may be 11B+, and may be implanted under the conditions that ion implantation energy is in a range of 3 to 8 keV. The dose of ions implanted may be in a range of 1×10¹⁵ to 5×10¹⁵ ions/cm³. Thus, a boron ion implanted layer 104 may be formed over the hydrogen ion implanted layer 102 of the donor wafer 100.

Next, as shown in FIG. 1C, annealing may be performed as a heat treatment so as to cut the donor wafer 100. The heat treatment may be performed at a temperature of 500° C. to 800° C. In this way, the boron ion implanted layer 104 of the donor wafer 100 may be cut.

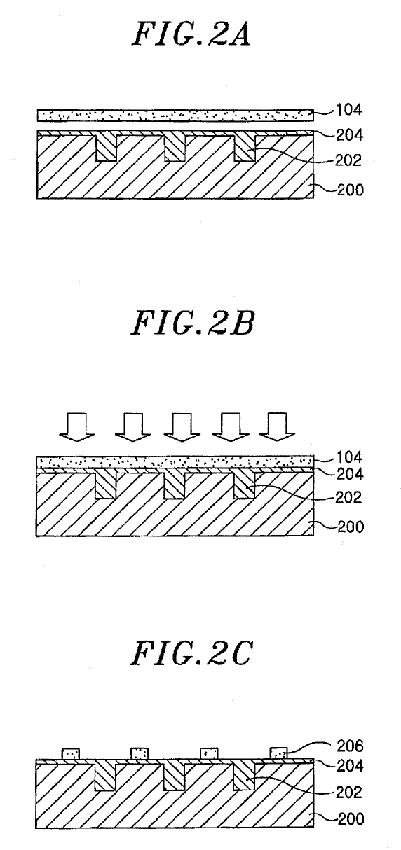

FIGS. 2A to 2C are process views showing a process of manufacturing a PMOS transistor according to embodiments. Referring to FIG. 2A, a silicon wafer may be prepared as a logic wafer 200. Trenches may be formed in the logic wafer 200 at prescribed or regular intervals so as to have a prescribed depth. An oxide material may be deposited in the formed trenches, and planarization may be performed by chemical mechanical polishing (CMP) so as to etch an unnecessary portion of the oxide film. In this way, a shallow trench isolation (hereinafter, referred to as STI) 202 may be formed.

Next, an oxynitride (SiON) film 204 serving as a gate insulating film may be formed over the entire surface of the logic wafer 200 having the shallow trench isolation 202 formed therein. Next, the donor wafer 104 cut in the step shown in FIG. 1C may be bonded to the logic wafer 200. The oxynitride film 204 for a p-type gate may be used as an adhesive material when the cut donor wafer 104 is bonded to the logic wafer 200.

After the wafers are bonded to each other, as shown in FIG. 2B, annealing may be performed so as to diffuse the ions, that is, 11B+, implanted into the transistor. In this case, the heat treatment may be performed at a temperature of 1000° C. to 1020° C.

Next, a mask may be deposited over the bonded donor wafer 104 so as to form transistors, and patterning may be performed. Thereafter, reactive ion etching (RIE) may be performed to form gate electrodes 206. Thus, a PMOS transistor having low resistance may be formed.

As described above, embodiments relate to lowering the electrostatic capacitance of a transistor so as to improve the operation characteristics of a PMOS device. Specifically, an ion-implanted donor wafer may be bonded onto a wafer having a tunnel oxide film formed thereon, and patterning may be performed so as to form a PMOS transistor having very low resistance.

It will be obvious and apparent to those skilled in the art that various modifications and variations can be made in the embodiments disclosed. Thus, it is intended that the disclosed embodiments cover the obvious and apparent modifications and variations, provided that they are within the scope of the appended claims and their equivalents.

What is claimed is:

1. An apparatus comprising:
a logic wafer to which a donor wafer implanted with boron ions is bonded, and over which a shallow trench isolation is formed; and
gate electrodes formed by performing a heat treatment on the bonded donor wafer, and after the heat treatment, by patterning the bonded donor wafer and performing reactive ion etching.

2. The apparatus of claim 1, wherein hydrogen ions are implanted into the donor wafer.

3. The apparatus of claim 2, wherein the donor wafer is cut by the heat treatment.

4. The apparatus of claim 1, wherein the logic wafer having the shallow trench isolation formed therein includes:
a shallow trench isolation formed by depositing an oxide material in trenches formed at prescribed intervals on the logic wafer, and planarizing the oxide material; and
a gate insulating film formed over the entire surface of the logic wafer having the shallow trench isolation formed therein.

5. The apparatus of claim 2, wherein the hydrogen ions are implanted with an ion implantation energy in a range of about 13 to 16 kev.

6. The apparatus of claim 2, wherein a dose of hydrogen ions implanted is in a range of about 1×10¹⁵ to 5×10¹⁵ ions/cm³.

7. The apparatus of claim 1, wherein the boron ions are implanted under the conditions that ion implantation energy is in a range of about 3 to 8 keV.

8. The apparatus of claim 1, wherein a dose of boron ions implanted is in a range of about 1×10¹⁵ to 5×10¹⁵ ions/cm³.

9. The apparatus of claim 4, wherein the gate insulating film is made of oxynitride.

10. A method comprising:
implanting the boron ions into a donor wafer;
bonding the donor wafer implanted with boron ions onto a logic wafer having a shallow trench isolation formed therein;
performing a heat treatment on the bonded donor wafer; and
after the heat treatment, forming gate electrodes by patterning the bonded donor wafer and performing reactive ion etching.

11. The method of claim 10, including implanting hydrogen ions into the donor wafer.

12. The method of claim 11, including cutting the donor wafer by performing the heat treatment on the donor wafer.

13. The method of claim 11, wherein a process of forming the logic wafer having the shallow trench isolation includes forming trenches at intervals on the logic wafer.

14. The method of claim 13, wherein a process of forming the logic wafer having the shallow trench isolation includes depositing an oxide material in the formed trenches and planarizing the oxide material so as to form the shallow trench isolation.

15. The method of claim 14, wherein a process of forming the logic wafer having the shallow trench isolation includes depositing a gate insulating film over the entire surface of the logic wafer having the shallow trench isolation formed therein.

16. The method of claim 11, wherein the hydrogen ions are implanted with an ion implantation energy in a range of about 13 to 16 kev.

17. The method of claim 11, wherein a dose of hydrogen ions implanted is in a range of about 1×10¹⁵ to 5×10¹⁵ ions/cm³.

18. The method of claim 10, wherein the boron ions are implanted with an ion implantation energy in a range of about 3 to 8 keV.

19. The method of claim 10, wherein a dose of boron ions implanted is in a range of about 1×10¹⁵ to 5×10¹⁵ ions/cm³.

20. The method of claim 13, wherein the gate insulating film is made of oxynitride.
